(19) United States
(12) Patent Application Publication
(10) Pub. No.: US 2005/0236101 A1
(43) Pub. Date: Oct. 27, 2005

(54) Method of manufacturing organic electro luminescent device, and electronic apparatus

(75) Inventor: Hidekazu Kobayashi, Toyoshina-machi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/103,630

(22) Filed: Apr. 12, 2005

(30) Foreign Application Priority Data
Apr. 27, 2004 (JP) 2004-131585

(51) Int. Cl. B32B 1/00

(52) U.S. Cl. 156/295; 156/275.5

(57) ABSTRACT

To bond a protection substrate on an organic EL element formation substrate using a curable resin without generating air bubbles in the curable resin in order to prevent oxygen or water from entering into an organic EL layer in an organic EL device. The protection substrate is supported at a plurality of locations by a plurality of support members. While individually adjusting the relative position of the support members to the element formation substrate, both substrates are bonded using the curable resin. At this time, the positions of the support members are controlled such that the curable resin is spread according to a predetermined pattern.

### BACKGROUND

The present invention relates to a method of manufacturing an organic electro-luminescent (EL) device arranged with a plurality of electro-luminescent elements for visually displaying information, an electronic apparatus equipped with the organic EL device, and a light emitting device used in a printer having a photoconductive drum for printing information.

For display devices equipped with a display panel formed of organic EL elements for emitting light modulated with information, for example, liquid crystal display devices, EL devices, surface field emission devices, etc., there is an increasing interest in isolating the display device from the atmosphere in order to prevent water or oxygen from entering into the display device, from the viewpoint of durability. Particularly, for an organic EL display that has been developed in recent years, there is a problem in that an organic emission material forming organic EL elements is susceptible to water or oxygen. Accordingly, as measures against this problem, various sealing methods have been considered.

For example, Japanese Unexamined Patent Application Publication No. 5-182759 discloses a method of sealing a protection substrate having low water permeability by adhering it with a wetproof photo-curable resin without using a conventional tubular airtight case. This method can achieve a small and frivolous type of the organic EL display.

[Patent Document 1] Japanese Unexamined Patent Application Publication No. 5-182759.

### SUMMARY

However, the above-mentioned sealing method has a problem in that air bubbles are apt to enter into the photo-curable resin when the protection substrate is adhered. The air bubbles entered into the resin deteriorates the durability of the display panel and, particularly, have a significantly bad influence on quality of a so-called top emission-type display panel where light is emitted from the protection substrate side.

Accordingly, it is an object of the present invention to provide an organic EL device having high durability without using the conventional tubular airtight case in order not to sacrifice advantages such as the lightness, the thinness and the miniaturization of a flat panel display.

It is another object of the present invention to provide a bonding method where it is difficult for air bubbles to occur.

It is yet another object of the present invention to provide a highly reliable electronic apparatus an organic EL device having high durability.

In order to achieve the above objects, there is provided a method of manufacturing an organic EL device including an element formation substrate on which an organic EL element are formed, and a protection substrate arranged on one side of the element formation substrate having an adhesive layer interposed therebetween, and the method comprises a step of disposing a curable resin on a bonding surface of the element formation substrate, the curable resin composing the adhesive layer; a support step of supporting the protection substrate for covering the element formation substrate at a plurality of locations on one surface of the protection substrate by a plurality of independently adjustable support members; a movement step of relatively moving the protection substrate supported at the plurality of locations above the element formation substrate; a partial contact step of contacting other side of the protection substrate with the curable resin by making some of the plurality of support members approach the element formation substrate; an extensive contact step of spreading the curable resin inserted between the element formation substrate and the protection substrate from a portion on which the curable resin is disposed to an outer side of the protection substrate by making at least other support members approach the element formation substrate; and a close adhesion step of closely adhering the protection substrate to the element formation substrate via the curable resin by using the plurality of support members.

According to the manufacturing method, in the step of closely adhering the element formation substrate to the protection substrate using the plurality of independently position-adjustable support members, the substrates can be bonded such that air bubbles are prevented from occurring in the curable resin. Accordingly, an organic EL device having excellent durability can be manufactured without deteriorating quality of display.

Preferably, the method of manufacturing an organic EL device further comprises a step of performing a positional alignment after the close adhesion step, and a step of curing the curable resin by radiating light or thermal energy on the curable resin.

According to the manufacturing method, the element formation substrate and the protection substrate are bonded such that both substrates are precisely aligned and integrally formed.

Preferably, in the extensive contact step, the relative position of each support member with respect to the element formation substrate is individually adjusted such that the curable resin inserted and spread between the element formation substrate and the protection substrate is spread according to a predetermined expansion pattern.

According to the manufacturing method, for example, by spreading the curable resin according to a series of predetermined expansion pattern in which the curable resin is sequentially spread, the curable resin is widely spread such that it has a uniform film thickness over the entire bonding surface, and the element formation substrate and the protection substrate are bonded to be integrally formed.

Preferably, in the extensive contact step, the expansion pattern of the curable resin is observed to adjust a position of each support member.

According to the manufacturing method, for example, by adjusting the position of the support members according to an actual spread state of the curable resin, the curable resin is successively spread according to the series of predetermined expansion patterns, and the element formation substrate and the protection substrate are bonded to be integrally formed.

Preferably, in the extensive contact step, the position of each support member is adjusted according to a program previously set corresponding to each kind of element formation substrate.

According to the manufacturing method, the element formation substrate and the protection substrate can be efficiently bonded according to an unevenness pattern of a surface of each element formation substrate of the organic EL device.

Preferably, in the extensive contact step, the plurality of support members successively approaches the element formation substrate from the portion, on which the curable resin is applied (disposed), to the outer side of the protection substrate.

According to the manufacturing method, even for an element formation substrate having an uneven bonding surface, the curable resin can be selectively disposed and spread.

Preferably, in the extensive contact step, the plurality of support members approaches the element formation substrate from a central portion of the protection substrate to the outer side of the protection substrate.

According to the manufacturing method, for example, since the curable resin can be spread from the central portion to both left and right ends, simultaneously, the extensive contact process can be terminated in a short time even in the case that an spreading area is large.

Preferably, in the extensive contact step, the plurality of support members approaches the element formation substrate from one end of the protection substrate to the other end of the protection substrate.

According to the manufacturing method, the curable resin can be spread even in the protection substrate having high stiffness.

Preferably, the bonding of the element formation substrate and the protection substrate is performed under a low-pressure atmosphere or an inert gas atmosphere.

With this configuration, the amount of water or oxygen existing in an atmosphere of the adhesion process can be reduced. The water or oxygen, which may be contained in the curable resin even if it exists in the atmosphere, can be excluded from the curable resin.

Preferably, the volume of the curable resin is a volume obtained from the product of a desired gap between the element formation substrate and the protection substrate and the area of a region to be sealed.

With this configuration, the curable resin can be spread to only a desired region without excess and deficiency of an adhesive at an end time of the lamination process.

In addition, the present invention provides an electronic apparatus having the organic EL device manufactured by the method of the present invention. Here, the electronic apparatus refers to a general apparatus comprising a circuit board or other components for showing a certain function, and is not particularly limited. For example, the electronic apparatus may include an IC card, a portable telephone, a video camera, a personal computer, a head mount display, a rear or front projector, a television (TV), a roll-up TV, a facsimile having a display function, a finder of a digital camera, a portable TV, a PDA, an electronic organizer, an electric bulletin board, an advertisement display, etc. In addition, the electronic apparatus of the present invention includes an electrophotographic printer (a printer having an electronic photography process) comprising the organic EL device of the present invention as a light emitting device for writing.

A method of manufacturing an organic EL device according to the present invention includes supporting a flexible protection substrate at a plurality of locations by a plurality of support members, individually adjusting the relative position of the support members with respect to an element formation substrate, and bonding both substrates using a curable resin. With this configuration, the element formation substrate and the protection substrate can be bonded with the film thickness of the curable resin maintained uniformly, without occurring the air bubbles in the curable resin. Accordingly, organic EL devices having high durability and excellent quality of display can be manufactured.

### BRIEF DESCRIPTION OF THE DRAWINGS

FIG. 1 is a schematic side view of an organic EL device according to the present invention;

FIGS. 2A-2F are explanatory diagrams illustrating a bonding process according to the present invention;

FIGS. 3A-3F are explanatory diagrams illustrating a bonding process according to a first embodiment of the present invention;

FIGS. 4A-4F are explanatory diagrams illustrating a bonding process according to a second embodiment of the present invention;

FIG. 5 is a flow chart illustrating a control algorithm of extensive contact processes according to a first embodiment of the present invention; and

FIGS. 6A-6D are diagrams illustrating examples of an electronic apparatus including the organic EL device according to the present invention.

### DETAILED DESCRIPTION OF EMBODIMENTS

Hereinafter, an organic EL device and a method of manufacturing the same according to the present invention will be described with reference to the accompanying drawings.

### First Embodiment

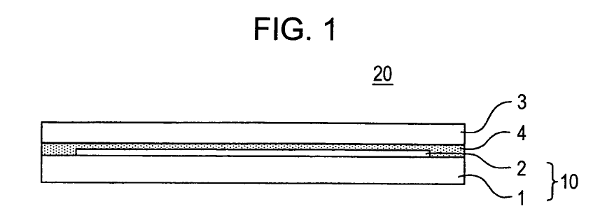

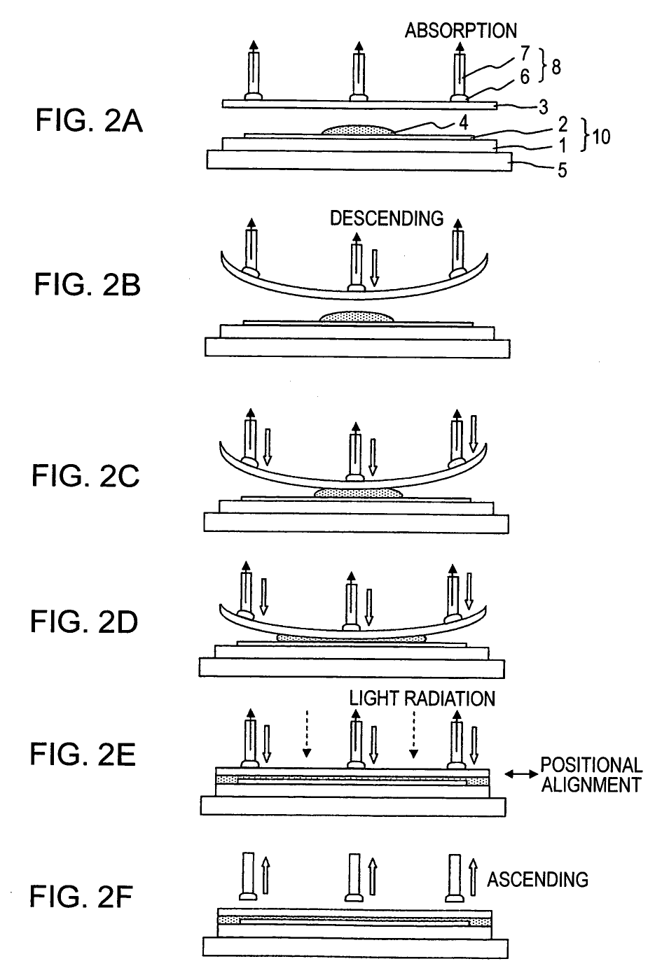

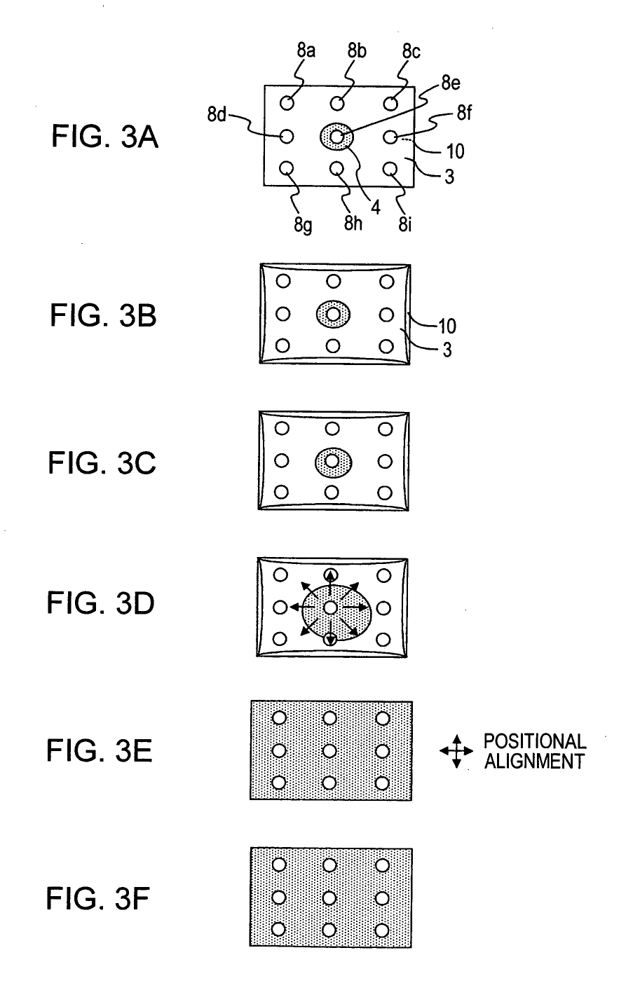

A first embodiment of the present invention will be described with reference to FIGS. 1 to 3. FIG. 1 is a schematic side view of an organic EL device manufactured by a manufacturing method of the present invention. FIGS. 2 and 3 are explanatory diagrams illustrating a manufacturing method of an organic EL device of the present invention.

This embodiment employs a method of bonding an element formation substrate and a flexible protection substrate by applying (or disposing) a photo-curable resin on a central portion of the element formation substrate and then spreading the photo-curable resin by contacting the flexible protection substrate with the element formation substrate expansionarily from the central portion to the outer side of the element formation substrate.

In FIG. 1, an organic EL device 20 includes an organic EL element 2 formed on an insulating substrate 1 such as a glass substrate or a resin substrate. An element formation substrate 10 having the organic EL element formed thereon is adhered to an insulating protection substrate 3 such as a glass substrate by means of a curable resin 4. With this configuration, the organic EL element 2 is isolated from the atmosphere by the protection substrate 3 and the curable resin 4, thereby preventing undesired oxygen or water from entering into the organic EL element.

Next, a manufacturing process of the organic EL device according to the first embodiment will be described with reference to FIG. 2. In FIG. 2(a), the substrate 1 on which the organic EL element 2 is formed is fixed to a workbench 5 by vacuum adsorption. The curable resin 4 such as a photo-curable resin (for example, a resin that becomes transparent after curing, such as modified acryl) is put (or disposed) on a central portion of the fixed element formation substrate 10 by a certain amount using a dispenser. This certain amount is roughly referred to as a volume obtained from the product of a desired gap between the substrate 1 and the protection substrate 3 and the area of a region to be sealed. The curable resin may be subject to a bubble removing process in a decompression chamber before it is used. A plurality of support members 8, each of which is composed of an adsorption pad 6 and a cylinder 7, supports one side of the protection substrate 3 at a plurality of points by vacuum adsorption, and the protection substrate 3 is disposed above the element formation substrate 10. In (b) of FIG. 2, a central portion of the protection substrate 3 is bent and supported in a convex shape in a direction of the element formation substrate 10 by positional movement of a support member 8 disposed in a central portion. In FIG. 2(c), while maintaining the state of FIG. 2(b), central portions of other convex sides of the protection substrate 3 contact with the curable resin 4 by positional movement of each support member 8. Next, as shown in FIG. 2(d), positions of peripheral support members are controlled to spread the curable resin 4 to the outer side. In FIG. 2(e), in a state where the element formation substrate 10 and the protection substrate 3 are bonded by the curable resin 4, each support member 8 is controlled to perform a positional alignment using an alignment mark and make the film thickness of the curable resin 4 uniform as a design value. Then, the curable resin 4 such as the photo-curable resin is cured by radiating light such as an ultraviolet ray on the curable resin 4. Next, as shown in FIG. 2, the absorption of the support members 8 is stopped and the support members 8 are moved upward.

Further, the first embodiment will be described in more detail with reference to FIG. 3. FIG. 3 is a schematic plan view when the manufacturing process of this embodiment is viewed from top. Processes of FIGS. 3(a) to (f) correspond to the processes of FIGS. 2(a) to (f), respectively.

In FIG. 3(a), the curable resin 4 is applied (disposed) on the central portion of the element formation substrate 10 by the certain amount. The protection substrate 3 is supported above the element formation substrate 10 by the support members 8a to 8i. Although the element formation substrate 10 is fixed to the workbench, it is omitted in this figure. Nine support members can individually adjust positions thereof. In FIG. 3(b), the central portion of the protection substrate is bent in a convex shape in the direction of the element formation substrate by positional movement of a central support member 8e, and is supported by absorption (vacuum adsorption) of the nine support members. In FIG. 3(c), the central portion of the protection substrate 3 partially contacts with the curable resin 4. Next, as shown in FIG. 3(d), while adjusting the positions of the support members, the curable resin 4 is spread to the outer side. In FIG. 3(d), since the contact position of the curable resin points faces toward the right and bottom direction, when the descending forces of the support members 8f, 8h, and 8i become weak and the descending forces of the support members 8a, 8b and 8d become strong, the contact position of the curable resin (or an expansion pattern of an outer peripheral of the curable resin) can be adjusted to reduce a possibility of permeation of air bubbles. Such a contact state of the curable resin is controlled by adjusting the positional movement of the support members such that the curable resin is successively spread according to a series of expansion pattern which is previously set while monitoring the spreading of the curable resin using a CCD camera. In FIG. 3(e), after the process of spreading the curable resin is terminated as the curable resin is spread over the entire contact surface, the positional alignment of the element formation substrate and the protection substrate is performed using the positional movement function of the support members, and then, the curable resin is cured by radiating light on the curable resin. Next, in FIG. 3(f), after bonding both substrates, absorption of the support members is stopped and the support members are separated from the protection substrate and are moved upward.

According to the manufacturing process as described above, the element formation substrate and the protection substrate can be bonded with the film thickness of the curable resin maintained uniformly, without generating (occurring) the air bubbles in the curable resin. Accordingly, since the organic EL element can be protected from oxygen or water, organic EL devices having high durability and excellent quality of display, which are also applicable to top emission-type displays, can be manufactured.

### Second Embodiment

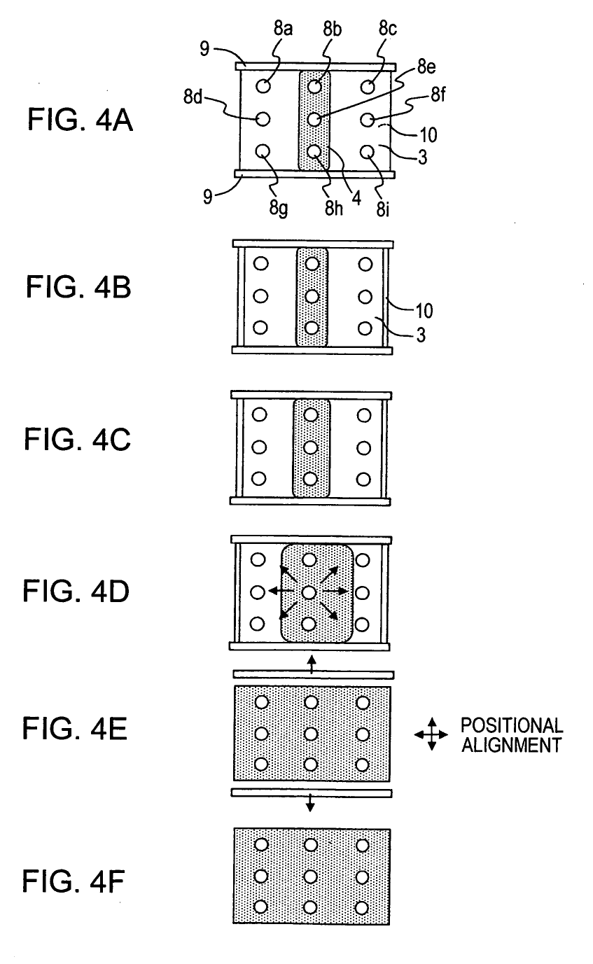

Now, a second embodiment will be described with reference to FIG. 4. FIG. 4 is a schematic plan view when the manufacturing process of this embodiment is viewed from top. Processes of FIG. 4(a) to FIG. 4(f) correspond to the processes of FIG. 2(a) to (f), respectively.

This embodiment employs an expansion pattern of bonding the element formation substrate and the protection substrate by applying (or disposing) the photo-curable resin on the central portion of the element formation substrate in a strip shape and by contacting the protection substrate with the element formation substrate expansively from the applied portion to the outer side of the element formation substrate.

In FIG. 4(a), the curable resin 4 is applied on the central portion of the element formation substrate 10 in a strip shape by a certain amount using a dispenser. In addition, a bar-shaped weir 9 is detachably provided in order to prevent the curable resin 4 from leaking out of the element formation substrate 10. One side of the protection substrate 3 is supported at a plurality of points by the support members 8a to 8i by electrostatic adsorption and the protection substrate 3 is disposed above the element formation substrate 10. Although the element formation substrate 10 is fixed to the workbench by the electrostatic adsorption, it is omitted in this figure. Nine support members can individually control a positional movement function. In FIG. 4(b), the central portion of the protection substrate is bent in a convex shape and in a strip shape in the direction of the element formation substrate by the positional movement function of the support members 8b, 8e and 8h, and is supported by each support member. In FIG. 4(c), bent portions of other surfaces of the protection substrate 3 contact with the curable resin 4. Next, as shown in FIG. 4(d), while adjusting the positions of the support members, the curable resin is spread to the outer right and left sides. In addition, in FIG. 4(d), the spread position of the curable resin is detected by the CCD camera that the expansion in the right is larger than that in the left. In this case, when the descending forces of the support members 8c, 8f, and 8i become weak and the descending forces of the support members 8a, 8d, and 8g become strong, the contact state of the curable resin can become uniform. In this way, the position of expansion of the curable resin is detected and the positional movement of the support members is adjusted according to a predetermined expansion pattern. In FIG. 4(e), after the process of spreading the curable resin is terminated, the bar-shaped weir 9 is moved and the positional alignment of the element formation substrate 10 and the protection substrate 3 is performed using the positional movement function of the support members. Then, the curable resin is cured by radiating light on the curable resin. In (f) of the figure, after bonding both substrates, absorption of the support members is stopped and the support members are moved upward.

According to the manufacturing process as described above, by conforming the contact state of the curable resin to the predetermined expansion pattern, the element formation substrate and the protection substrate can be bonded and the film thickness of the curable resin is maintained uniformly, without occurring the air bubbles in the curable resin. Accordingly, organic EL devices having high durability and excellent quality of display, which are also applicable to top emission-type displays, can be manufactured.

In addition, since the weir can prevent the curable resin from leaking out of the element formation substrate, an end surface of the organic EL device can be clearly maintained.

In addition, when both substrates are bonded under decompression, vacuum adsorption cannot be used as an adsorption mechanism of the support members. In this case, the electrostatic adsorption may be used as the adsorption mechanism.

In addition, although the bonding process may be performed under an air atmosphere, it is preferably performed under a low-pressure atmosphere or an inert gas (for example, nitrogen) atmosphere since oxygen or water can be excluded under this atmosphere.

In addition, for the support members, in consideration of various conditions such as the size of the element formation substrate, the weight, thickness and hardness of the supported protection substrate, the viscosity of the curable resin used, or the atmosphere of the bonding process, the kind, number, arrangement, absorption force, and positional movement control of the support members may be properly optimized.

In addition, if parameters of the extensive contact processes are programmized for each element formation substrate based on the above-mentioned optimization conditions on the support members, the bonding of the substrates can efficiently cope with a change of the device.

### Third Embodiment

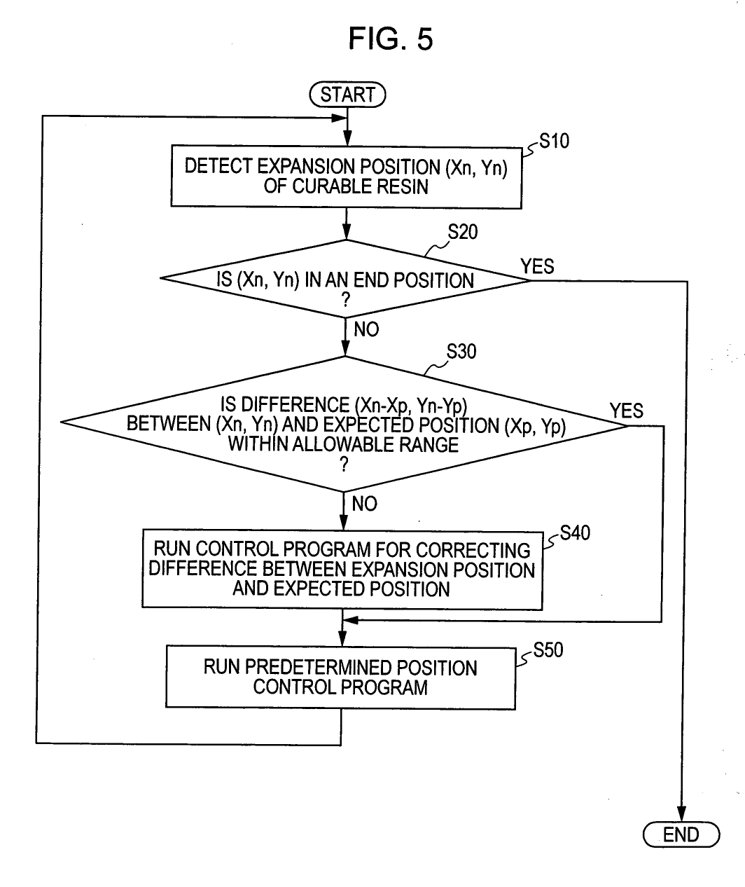

A third embodiment of the present invention provides a program for controlling the extensive contact processes of the curable resin inserted and spread between the element formation substrate and the protection substrate and shows an example of a basic algorithm. FIG. 5 is a flow chart showing the above algorithm.

In FIG. 5, although a program (S50 in the figure) which is previously set in order to adjust the position of the support members and a control program (S40 in the figure) for correcting a difference between an expansion position and an expected position of the curable resin in the extensive contact processes are individually prepared, explanation thereof will be omitted in this embodiment.

First, as shown in Step S10 in the figure, the expansion position of the curable resin in the extensive contact processes is detected. Next, if it is determined in Step S20 that the detected position (Xn, Yn) is not an end position, the process proceeds to Step S30 where a difference between the detected position (Xn, Yn) and the predetermined expected position (Xp, Yp) is calculated. If this difference (X=Xn-Xp, Y=Yn-Yp) is within an allowable range, the predetermined program (Step S50) for controlling the extensive contact process continues to run to spread the contact area of the curable resin. If this difference (X, Y) exceeds the allowable range, the program (Step S40) for correcting the difference continues to run until the difference goes within the allowable range. When the detected position (Xn, Yn) reaches the end position in Step S20, the extensive contact processes are terminated.

The above-described algorithm runs for all support members disposed at the plurality of locations. When the control program of the extensive contact processes is prepared for each kind of element formation substrate, based on the basic algorithm, the extensive contact processes of the curable resin inserted and spread between the element formation substrate and the protection substrate can be controlled according to the predetermined expansion pattern such that air bubbles are prevented from occurring in the curable resin and the film thickness of the curable resin is uniformly maintained.

In addition, the predetermined expansion pattern of the curable resin or the position control program for the support members is preferably prepared with various parameters optimized based on results of tests performed in advance.

### Fourth Embodiment

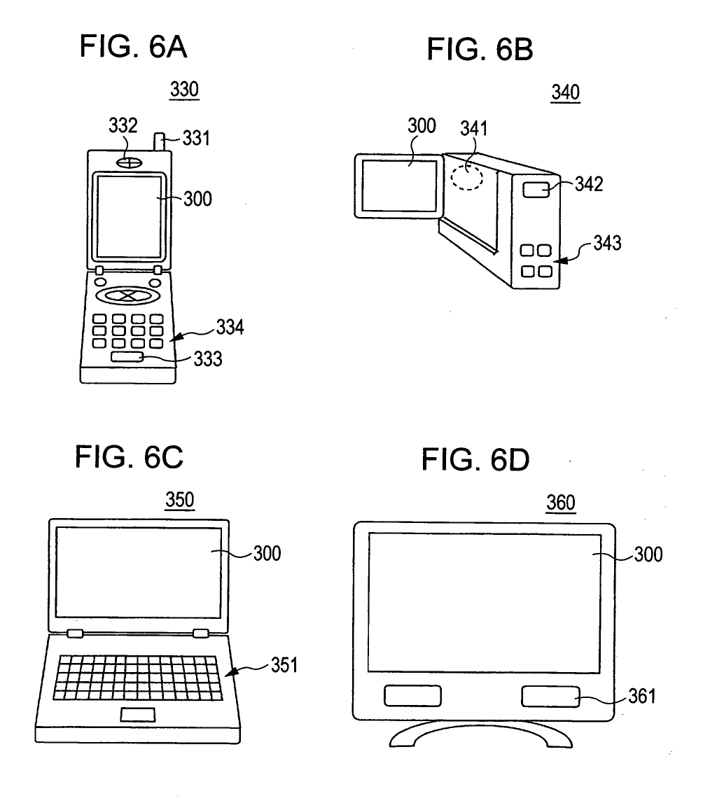

Now, an electronic apparatus including an organic EL unit equipped with the organic EL device according to the present invention will be described with reference to FIG. 6. FIG. 6 is an explanatory diagram of examples of an electronic apparatus including the above-described organic EL device.

FIG. 6(A) shows an example of the application of the present invention to an portable telephone, where a portable telephone 330 includes an antenna unit 331, a voice output unit 332, a voice input unit 333, a manipulating unit 334, and an organic EL device 300 according to the present invention. In this way, the organic EL device of the present invention is usable as a display. FIG. 6(B) shows an example of the application of the present invention to a video camera, where a video camera 340 includes an image receiving unit 341, a voice input unit 342, a manipulating unit 343, and an organic EL device 300 according to the present invention. FIG. 6(C) shows an example of the application of the present invention to a notebook PC, where a notebook PC 350 includes a manipulating unit 351 and an organic EL device 300 according to the present invention. In addition, similarly, the organic EL device of the present invention is applicable to a monitor apparatus used for a personal computer and so on. FIG. 6(D) shows an example of the application of the present invention to a television, where a television 360 includes a manipulating unit 351 and an organic EL device 300 according to the present invention. In addition, the organic EL device of the present invention is applicable to other electronic apparatuses comprising displays, which is not limited to the above-mentioned electronic apparatuses. For example, the organic EL device of the present invention is applicable to a facsimile apparatus comprising a display, a finder of a digital camera, a portable TV, an electronic organizer, an electric bulletin board, an advertisement display, etc. In addition to the case where the organic EL device of the present invention is contained in the above-mentioned electronic apparatuses, the organic EL device is utilized as independent components of electronic apparatuses.

In addition, the present invention is not limited to the above-described embodiments and may be practiced with various modifications, changes and alterations without deviating from the scope and spirit of the present invention. For example, instead of a laser or a LED head for writing of a electrophotographic printer, the organic EL device of the present invention may be equipped as a light emitting device in the printer, resulting in downsizing and low costs of the printer.

Furthermore, materials of the protection substrate and the curable resin may be used properly depending on the embodiments.

1. A method of manufacturing an organic EL device including an element-formed substrate on which organic EL elements are formed, and a protective substrate arranged on one side of the element-formed substrate having an adhesive layer interposed therebetween,
the method comprising:
a step of disposing a curable resin on a bonding surface of the element-formed substrate, the curable resin composing the adhesive layer;
a support step of supporting the protective substrate for covering the element-formed substrate at a plurality of locations on one surface of the protective substrate by a plurality of independently adjustable support members;
a movement step of relatively moving the protective substrate supported at the plurality of locations above the element-formed substrate;
a partial contact step of contacting the other side of the protective substrate with the curable resin by making some of the plurality of support members approach the element-formed substrate;
an extensive contact step of spreading the curable resin inserted between the element-formed substrate and the protective substrate from a portion on which the curable resin is disposed to an outer side of the protective substrate by making at least other support members approach the element-formed substrate; and
a close adhesion step of closely adhering the protective substrate to the element-formed substrate via the curable resin by using the plurality of support members.

2. The method of manufacturing an organic EL device according to claim 1, further comprising:
a positional alignment step of performing a positional alignment after the close adhesion step; and
a resin curing step by radiating light or thermal energy on the curable resin.

3. The method of manufacturing an organic EL device according to claim 1, wherein, in the extensive contact step, the relative position of each support member with respect to the element formation substrate is individually adjusted such that the curable resin inserted and spread between the element-formed substrate and the protective substrate is spread according to a predetermined expansion pattern.

4. The method of manufacturing an organic EL device according to claim 3, wherein, in the extensive contact step, the expansion pattern of the curable resin is observed to adjust a position of each support member.

5. The method of manufacturing an organic EL device according to claim 3, wherein, in the extensive contact step, the position of each support member is adjusted according to a program previously set corresponding to each kind of element-formed substrate.

6. The method of manufacturing an organic EL device according to claim 3, wherein, in the extensive contact step, the plurality of support members successively approaches the element-formed substrate from the portion on which the curable resin is disposed to the outer side of the protective substrate.

7. The method of manufacturing an organic EL device according to claim 1, wherein, in the extensive contact step, the plurality of support members approaches the element-formed substrate from a central portion of the protective substrate to the outer side of the protective substrate.

8. The method of manufacturing an organic EL device according to claim 3, wherein, in the extensive contact step, the plurality of support members approaches the element-formed substrate from one end of the protective substrate to the other end of the protective substrate.

9. The method of manufacturing an organic EL device according to claim 1, wherein the method of manufacturing an organic EL device is performed under a low-pressure atmosphere.

10. The method of manufacturing an organic EL device according to claim 1, wherein the method of manufacturing an organic EL device is performed under an inert gas atmosphere.

11. The method of manufacturing an organic EL device according to claim 1, wherein the volume of the curable resin is a volume obtained from the product of a desired gap between the element formation substrate and the protection substrate and the area of a region to be sealed.

12. An electronic apparatus comprising the organic EL device manufactured according to claim 1.
